(19) United States
(12) Patent Application Publication
(10) Pub. No.: US 2013/0314834 A1
(43) Pub. Date: Nov. 28, 2013

(54) SEMICONDUCTOR DRIVING CIRCUIT AND SEMICONDUCTOR DEVICE

(71) Applicants: Koji TAMAKI, Fukuoka-shi (JP); Takahiro INOUE, Tokyo (JP); Hiroyuki OKABE, Tokyo (JP)

(72) Inventors: Koji TAMAKI, Fukuoka-shi (JP); Takahiro INOUE, Tokyo (JP); Hiroyuki OKABE, Tokyo (JP)

(21) Appl. No.: 13/727,231

(22) Filed: Dec. 26, 2012

(30) Foreign Application Priority Data
May 28, 2012 (JP) 2012-120821

(51) Int. Cl. H03K 17/06; H02H 3/08

(52) U.S. Cl. CPC H03K 17/06; H02H 3/08
USPC 361/93.1; 327/109

(57) ABSTRACT

A low power consumption semiconductor driving circuit is provided which applies positive and negative bias signals to a semiconductor switching element by using a single power source to perform the switching of the semiconductor switching element. The semiconductor driving circuit is a semiconductor driving circuit for driving the semiconductor switching element. The semiconductor driving circuit includes an internal power source circuit for generating a second voltage from a first voltage supplied from an external power source, and a driver for applying the first voltage or the second voltage between the gate and emitter of the semiconductor switching element in accordance with an input signal inputted from outside to switch on and off the semiconductor switching element. The internal power source circuit is configured to operate in accordance with the input signal.

### BACKGROUND OF THE INVENTION

1. Field of the Invention

The present invention relates to a semiconductor driving circuit and a semiconductor device and, more particularly, to a semiconductor driving circuit for driving a semiconductor switching element.

2. Description of the Background Art

A method of applying a driving signal to a semiconductor switching element in an off state in a negative bias direction for the purpose of ensuring the off state of the switching element has been generally used as a method of driving a semiconductor switching element such as an IGBT, a MOSFET and a bipolar transistor.

In general, it has been known to prepare a positive biasing power source and a negative biasing power source and to turn on and off a complementary pair of transistors alternately, thereby providing driving signals for positive bias and negative bias.

There is another technique in which a negative biasing power source is formed by taking a constant voltage out of a single positive biasing power source. This technique is such that, for example, when a positive bias is applied, the positive biasing power source is used to charge a capacitor, thereby forming the negative biasing power source, as disclosed in Japanese Patent Application Laid-Open No 9-140122 (1997).

The aforementioned background art techniques require the positive biasing power source and the negative biasing power source to give rise to the increase in circuit size, thereby resulting in the increase in costs. Also, even when the negative biasing power source is used also as the positive biasing power source, a negative bias signal is always applied to a semiconductor switching element. It is hence necessary that voltage on the single power source is greater by the amount corresponding to the magnitude of the negative bias signal. This results in a problem such that power consumption is increased. When a capacitor is used for the negative biasing power source, it is also necessary that the capacitance of the capacitor is sufficiently greater than the gate capacitance of the semiconductor switching element. This results in a problem such that costs and circuit size are increased.

### SUMMARY OF THE INVENTION

It is therefore an object of the present invention to provide a low power consumption semiconductor driving circuit which applies positive and negative bias signals to a semiconductor switching element by using a single power source to perform the switching of the semiconductor switching element.

According to the present invention, a semiconductor driving circuit for driving a semiconductor switching element includes: an internal power source circuit, and a driver. The internal power source circuit generates a second voltage from a first voltage supplied from an external power source. The driver applies the first voltage or the second voltage between the gate and emitter of the semiconductor switching element in accordance with an input signal inputted from outside to switch on and off the semiconductor switching element. The internal power source circuit is configured to operate in accordance with the input signal.

The second voltage generated by the internal power source circuit of the semiconductor driving circuit according to the present invention is equal to zero when the input signal inputted to the driver is a positive bias signal, and is equal to a constant voltage when the input signal is a negative bias signal. In this manner, the second voltage is varied in accordance with the input signal. This eliminates the need to make the first voltage for switching on the semiconductor switching element greater by the amount corresponding to the constant voltage. This allows the decrease in the first voltage supplied from the external power source. It is therefore expected that power consumption is reduced.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a circuit diagram of a semiconductor driving circuit according to a prerequisite technique;

FIGS. 2A, 2B and 2C are graphs showing the operations of semiconductor driving circuits according to the prerequisite technique and a first preferred embodiment of the present invention;

FIG. 3 is a circuit diagram of the semiconductor driving circuit according to the first preferred embodiment;

FIG. 4 is a circuit diagram of the semiconductor driving circuit according to a second preferred embodiment of the present invention;

FIG. 5 is a circuit diagram of the semiconductor driving circuit according to a third preferred embodiment of the present invention; and

FIG. 6 is a circuit diagram of the semiconductor driving circuit according to a fourth preferred embodiment of the present invention.

### DESCRIPTION OF THE PREFERRED EMBODIMENTS

### Prerequisite Technique

<Structure>

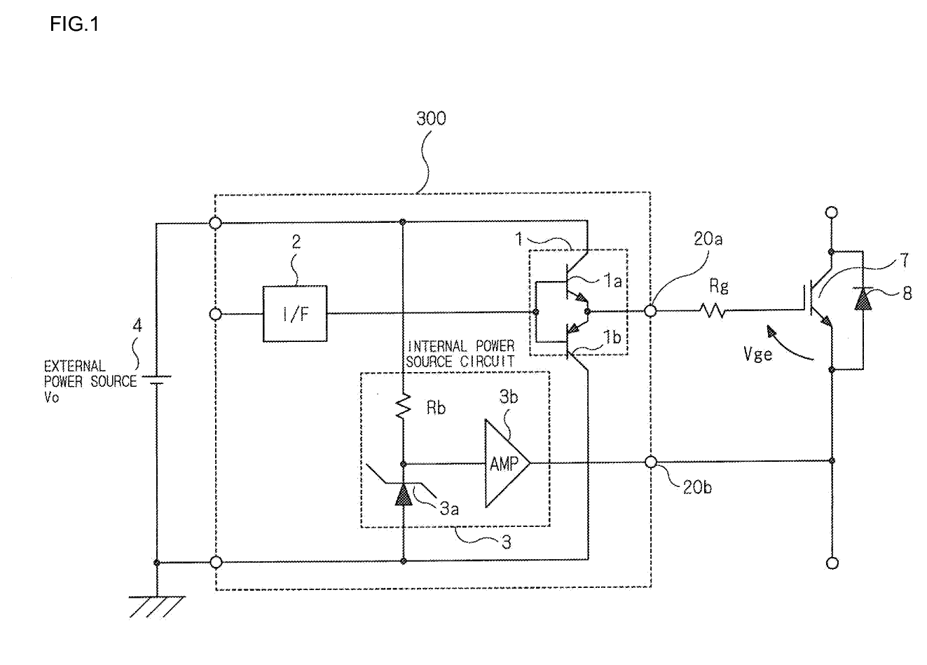

Prior to description on preferred embodiments according to the present invention, a technique presented as a prerequisite for the present invention will be described. FIG. 1 is a circuit diagram of a semiconductor driving circuit 300 according to the prerequisite technique. The semiconductor driving circuit 300 includes a driver 1 having a complementary pair of transistors 1a and 1b for controlling the switching on and off of a semiconductor switching element 7. The semiconductor driving circuit 300 is driven by an external power source 4 for supplying a first voltage (V₀). The semiconductor driving circuit 300 further includes an internal power source circuit 3 connected in parallel with the external power source 4. Input signals (a positive bias signal and a negative bias signal) for controlling the switching on and off of the semiconductor switching element 7 are inputted through an interface (I/F) 2 to the common gate of the transistors 1a and 1b.

The semiconductor driving circuit 300 has a terminal 20a connected through a gate resistor Rg to the gate of the semiconductor switching element 7, and a terminal 20b connected to the emitter of the semiconductor switching element 7. Examples of the semiconductor switching element 7 include an IGBT, a MOSFET and a bipolar transistor. A freewheeling diode 8 is connected in parallel with the semiconductor switching element 7 to protect the semiconductor switching element 7 against feedback currents.

The internal power source circuit 3 includes a resistor Rb and a Zener diode 3a which are connected in series and disposed in parallel with the external power source 4. A point of connection of the resistor Rb and the Zener diode 3a is connected through a buffer amplifier 3b to the terminal 20b. The internal power source circuit 3 generates a second voltage from the external power source 4 to apply a reverse bias voltage to the semiconductor switching element 7.

<Operation>

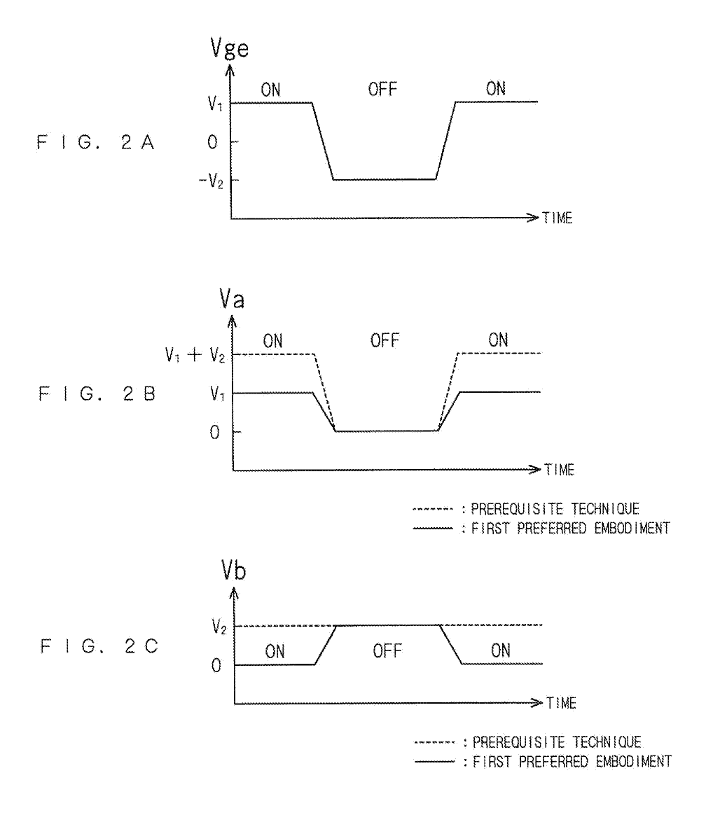

As shown in FIG. 2A, a forward bias voltage V₁ and a reverse bias voltage V₂ are applied as a gate-emitter voltage (Vge) to the semiconductor switching element 7 to switch on and off the semiconductor switching element 7.

FIGS. 2B and 2C show voltages Va and Vb on the terminals 20a and 20b, respectively, of the semiconductor driving circuit 300 according to the prerequisite technique.

When the positive bias signal is outputted from the interface (I/F) 2 to the driver 1, the upper transistor 1a of the complementary pair is switched on, and the lower transistor 1b thereof is switched off, so that the first voltage (V₀) equal to V₁+V₂ is applied to the terminal 20a, as indicated by broken lines in FIG. 2B. At this time, the second voltage generated by the internal power source circuit 3, i.e. the voltage Vb on the terminal 20b, is constantly equal to V₂ (as indicated by broken lines in FIG. 2C), irrespective of whether the semiconductor switching element 7 is on or off. As a result, the gate-emitter voltage Vge is equal to V₁, so that the semiconductor switching element 7 is switched on.

On the other hand, when the negative bias signal is outputted from the interface (I/F) 2 to the driver 1, the lower transistor 1b of the complementary pair is switched on, and the upper transistor 1a thereof is switched off, so that the voltage Va on the terminal 20a is equal to zero. The voltage Vb on the terminal 20b is constantly equal to V₂. As a result, the gate-emitter voltage Vge is equal to −V₂, so that the semiconductor switching element 7 is switched off.

For switching shown in FIG. 2A in the aforementioned circuit configuration, it is necessary that the first voltage (V₀) supplied from the external power source 4 is equal to V₁+V₂. This is because the second voltage generated from the first voltage by the internal power source circuit 3 is constantly equal to V₂, irrespective of whether the semiconductor switching element 7 is on or off. For reduction in power consumption, it is preferable that the semiconductor driving circuit can be driven by an external power source with a lower voltage.

### First Preferred Embodiment

<Structure>

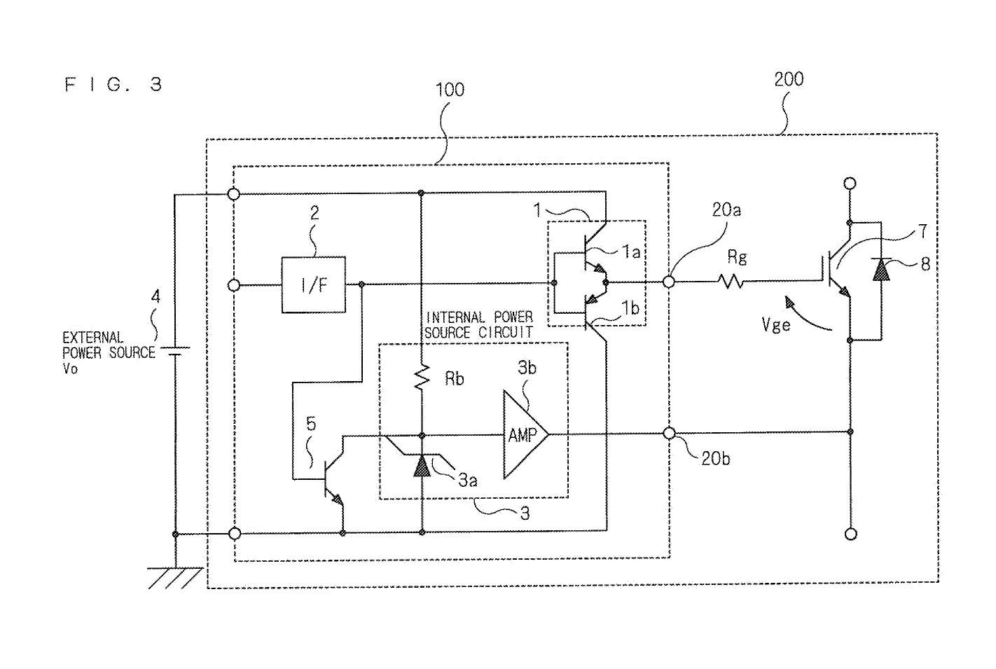

FIG. 3 is a circuit diagram of a semiconductor driving circuit 100 according to a first preferred embodiment of the present invention. The semiconductor driving circuit 100 includes a switching circuit connected in parallel with the Zener diode 3a provided in the internal power source circuit 3 in addition to the components of the semiconductor driving circuit 300 of the prerequisite technique (with reference to FIG. 1). A transistor 5 is used as the switching circuit in the first preferred embodiment. A signal from the interface (I/F) 2 is applied to the gate of the transistor 5 to switch on and off the transistor 5. Examples of the transistor 5 include a bipolar transistor and a MOSFET.

A semiconductor device 200 includes the semiconductor driving circuit 100, the semiconductor switching element 7, the gate resistor Rg connected to the gate of the semiconductor switching element 7, and the freewheeling diode 8 connected in parallel with the semiconductor switching element 7. Other parts of the first preferred embodiment are identical with those of the prerequisite technique (with reference to FIG. 1), and will not be described.

<Operation>

As shown in FIG. 2A, the forward bias voltage V₁ and the reverse bias voltage V₂ are applied as the gate-emitter voltage (Vge) between the gate and emitter of the semiconductor switching element 7 to switch on and off the semiconductor switching element 7. The voltages Va and Vb on the terminals 20a and 20b are shown in FIGS. 2B and 2C, respectively.

When the positive bias signal is outputted from the interface (I/F) 2 to the driver 1, the upper transistor 1a of the complementary pair is switched on, and the lower transistor 1b thereof is switched off. The transistor 5 is switched on. Thus, the first voltage (V₀) supplied from the external power source 4 is outputted as an on state voltage to the terminal 20a, as indicated by solid lines in FIG. 2B. In the first preferred embodiment, the first voltage (V₀) supplied from the external power source 4 is equal to the forward bias voltage V₁. At this time, the voltage Vb on the terminal 20b is equal to zero. As a result, the gate-emitter voltage Vge is equal to V₁, so that the semiconductor switching element 7 is switched on. Unlike the prerequisite technique, the voltage Vb on the terminal 20b is equal to zero, rather than V₂, in the on state for the following reason. The transistor 5 is switched on by receiving the positive bias signal from the interface (I/F) 2, so that no voltage is applied to the Zener diode 3a. Accordingly, the second voltage generated by the internal power source circuit 3 is equal to zero.

On the other hand, when the negative bias signal is outputted from the interface (I/F) 2 to the driver 1, the lower transistor 1b of the complementary pair is switched on and the upper transistor 1a thereof is switched off. The transistor 5 is switched off. Thus, the voltage Va on the terminal 20a is equal to zero, and the second voltage generated by the internal power source circuit 3, i.e. the voltage Vb on the terminal 20b, is equal to V₂. As a result, the gate-emitter voltage Vge is equal to −V₂, so that the semiconductor switching element 7 is switched off.

As described above, the second voltage generated by the internal power source circuit 3 is equal to zero or V₂ in accordance with the signal outputted from the interface (I/F) 2 to the driver 1. It is hence only necessary that the voltage on the external power source 4, i.e. the first voltage (V₀), is made equal in magnitude to the forward bias voltage V₁. Thus, the first preferred embodiment is capable of decreasing the voltage on the external power source 4 by the amount equal to V₂ as compared with the aforementioned prerequisite technique to achieve the reduction in power consumption.

In the first preferred embodiment, when the voltage on the external power source 4, i.e. the first voltage (V₀), is made equal to V₁+V₂ as in the prerequisite technique, a sufficient voltage is applied to the gate of the semiconductor switching element 7 to reduce the on-state resistance of the semiconductor switching element 7. This achieves the reduction in power consumption resulting from the reduction in on-state resistance.

<Effect>

The semiconductor driving circuit 100 according to the first preferred embodiment is the semiconductor driving circuit 100 for driving the semiconductor switching element 7 (for example, a power transistor). The semiconductor driving circuit 100 includes the internal power source circuit for generating the second voltage from the first voltage supplied from the external power source 4, and the driver for applying the first voltage or the second voltage between the gate and emitter of the semiconductor switching element 7 in accordance with the input signal inputted from the outside to switch on and off the semiconductor switching element 7. The internal power source circuit 3 is characterized by operating in accordance with the input signal.

Thus, the second voltage generated by the internal power source circuit 3 is equal to zero when the input signal inputted to the driver 1 is the positive bias signal, and is equal to V₂ when the input signal is the negative bias signal. In this manner, the second voltage is varied in accordance with the input signal This allows the first voltage for switching on the semiconductor switching element 7 to be equal to V₁. Thus, the first preferred embodiment is capable of decreasing the first voltage (V₀) from V₁+V₂ to V₁, as compared with the prerequisite technique. It is therefore expected that power consumption is reduced.

The semiconductor driving circuit 100 according to the first preferred embodiment further includes the switching circuit, i.e. the transistor 5, which is switched on and off in accordance with the input signal. The internal power source circuit 3 generates the second voltage, and includes the Zener diode 3a connected in parallel with the transistor 5.

Since the transistor 5 is connected in parallel with the Zener diode 3a, the second voltage is made equal to V₂ by the Zener diode 3a when the input signal from the interface (I/F) 2 is the negative bias signal, and the second voltage is equal to zero when the transistor 5 is on, that is, when the input signal is the positive bias signal. Thus, the first preferred embodiment is capable of decreasing the voltage on the external power source 4 to V₁, as compared with the prerequisite technique. It is therefore expected that power consumption is reduced.

Also, the semiconductor device 200 according to the first preferred embodiment includes the semiconductor driving circuit 100 and the semiconductor switching element 7. Thus, the voltage on the external power source 4 is lower than that in the prerequisite technique. This achieves the size reduction of the external power source 4 to accordingly achieve the size reduction of an apparatus incorporating the semiconductor device 200.

The semiconductor switching element 7 in the semiconductor device 200 according to the first preferred embodiment is characterized by containing SiC. This allows the semiconductor switching element 7 to perform high-speed switching at an elevated temperature. Also, the capability of operating at an elevated temperature allows the simplification of the heat dissipation structure of the entire semiconductor device 200.

Also, the semiconductor switching element 7 in the semiconductor device 200 according to the first preferred embodiment is characterized by containing GaN. This allows the semiconductor switching element 7 to perform high-speed switching at an elevated temperature. Also, the capability of operating at an elevated temperature allows the simplification of the heat dissipation structure of the entire semiconductor device 200.

### Second Preferred Embodiment

<Structure>

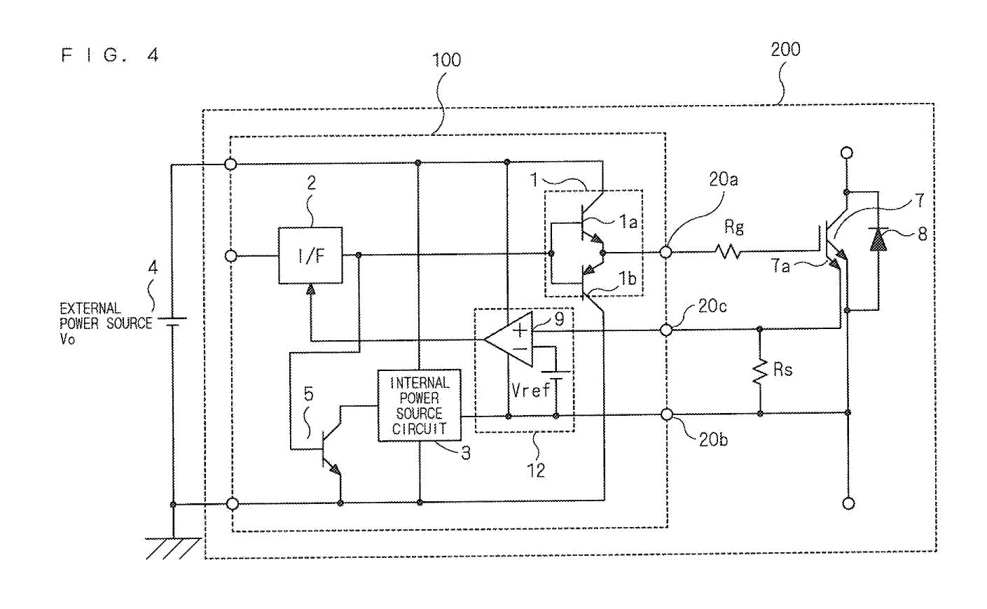

FIG. 4 is a circuit diagram of the semiconductor driving circuit 100 and the semiconductor device 200 according to a second preferred embodiment of the present invention. The semiconductor switching element 7 (for example, an IGBT) according to the second preferred embodiment further includes a sense element. The sense element includes a sense terminal 7a through which a current proportional to a main current of the semiconductor switching element 7 flows, and a sense resistor Rs connected between a main terminal and the sense terminal 7a and for converting a sense current into voltage.

The semiconductor driving circuit 100 according to the second preferred embodiment further includes an overcurrent detector 12 in addition to the components of the semiconductor driving circuit 100 of the first preferred embodiment. The overcurrent detector 12 detects the sense current flowing through the aforementioned sense element. When the sense current exceeds a predetermined value, the overcurrent detector 12 switches off the semiconductor switching element 7 to protect the semiconductor switching element 7 against overcurrent.

The overcurrent detector 12 according to the second preferred embodiment includes a comparator 9 and a power source Vref. The comparator 9 has a positive phase input connected to a terminal 20c, and a negative phase input connected to the power source Vref. A reference potential for the power source Vref is connected to the output of the internal power source circuit 3 (i.e., the terminal 20b).

<Operation>

The operation of switching on and off the semiconductor switching element 7 in the second preferred embodiment is similar to that in the first preferred embodiment, and will not be described.

When the semiconductor switching element 7 is on, the sense current flows through the sense resistor Rs to thereby generate a sense voltage Vs across the sense resistor Rs, i.e. between the terminals 20b and 20c. The comparator 9 makes a comparison between the sense voltage Vs and a voltage on the power source Vref. When the sense voltage Vs exceeds the voltage on the power source Vref, a high signal is inputted from the comparator 9 to the interface (I/F) 2.

The sense voltage Vs is proportional to the sense current. Thus, the sense voltage Vs obtained when the sense current exceeds the predetermined value may be determined as the voltage on the power source Vref, whereby the high signal is outputted from the comparator 9 when the sense current exceeds the predetermined value.

When the high signal is inputted to the interface (I/F) 2, the interface (I/F) 2 outputs the negative bias signal to switch off the semiconductor switching element 7. This protects the semiconductor switching element 7 against overcurrent to prevent damages to the semiconductor switching element 7.

<Effect>

The semiconductor switching element 7 in the semiconductor driving circuit 100 according to the second preferred embodiment includes the sense element (the sense terminal 7a and the sense resistor Rs) through which current flows in any ratio to the main current of the semiconductor switching element 7. The semiconductor driving circuit 100 according to the second preferred embodiment further includes the overcurrent detector 12 for detecting the sense current flowing through the sense element. The overcurrent detector 12 switches off the semiconductor switching element 7 when the sense current exceeds the predetermined value.

Thus, the sense element and the overcurrent detector 12 are capable of detecting the overcurrent condition and the short circuit condition of the semiconductor switching element 7 to switch off the semiconductor switching element 7 at an early stage, thereby preventing damages to the semiconductor switching element 7. Therefore, the durability of the semiconductor driving circuit 100 is improved.

Also, the semiconductor device 200 according to the second preferred embodiment includes, the semiconductor driving circuit 100, the sense element (the sense terminal 7a and the sense resistor Rs), and the semiconductor switching element 7. Thus, as in the first preferred embodiment, the voltage on the external power source 4 is lower than that in the prerequisite technique. This achieves the size reduction of the external power source 4 to accordingly achieve the size reduction of an apparatus incorporating the semiconductor device 200.

Further, the overcurrent detector 12 detects the sense current flowing through the sense element. The overcurrent detector 12 is capable of switching off the semiconductor switching element 7 when the sense current exceeds the predetermined value because the main current becomes excessively high. This prevents damages to the semiconductor switching element 7. Therefore, the durability of the semiconductor device 200 is improved.

### Third Preferred Embodiment

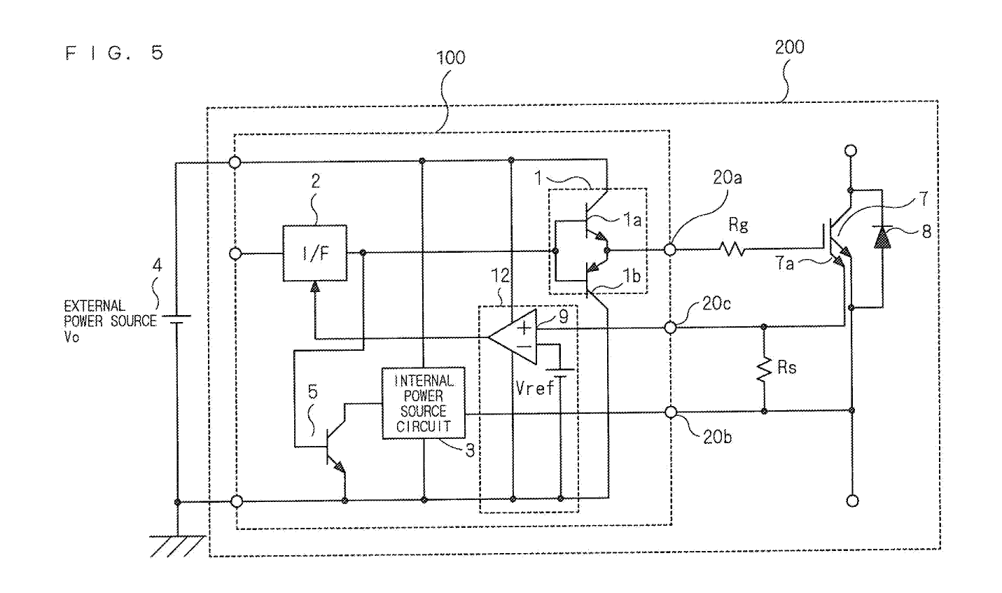

FIG. 5 is a circuit diagram of the semiconductor driving circuit 100 and the semiconductor device 200 according to a third preferred embodiment of the present invention. In the overcurrent detector 12 according to the third preferred embodiment, the reference potential of the power source Vref is equal to the reference potential of the first voltage, i.e. a ground potential. Other structures of the third preferred embodiment are identical with those of the second preferred embodiment (with reference to FIG. 4), and will not be described.

The decrease in the reference potential of the power source Vref allows the voltage on the power source Vref to be higher than that in the second preferred embodiment (with reference to FIG. 4). Thus, misoperation of the overcurrent detection due to noise, for example, is less prone to occur.

In the semiconductor driving circuit 100 according to the third preferred embodiment, the reference potential of the overcurrent detector 12 is characterized by being equal to the reference potential of the first voltage. This allows the voltage on the power source Vref to be higher, so that misoperation of the overcurrent detection due to noise and the like is less prone to occur.

### Fourth Preferred Embodiment

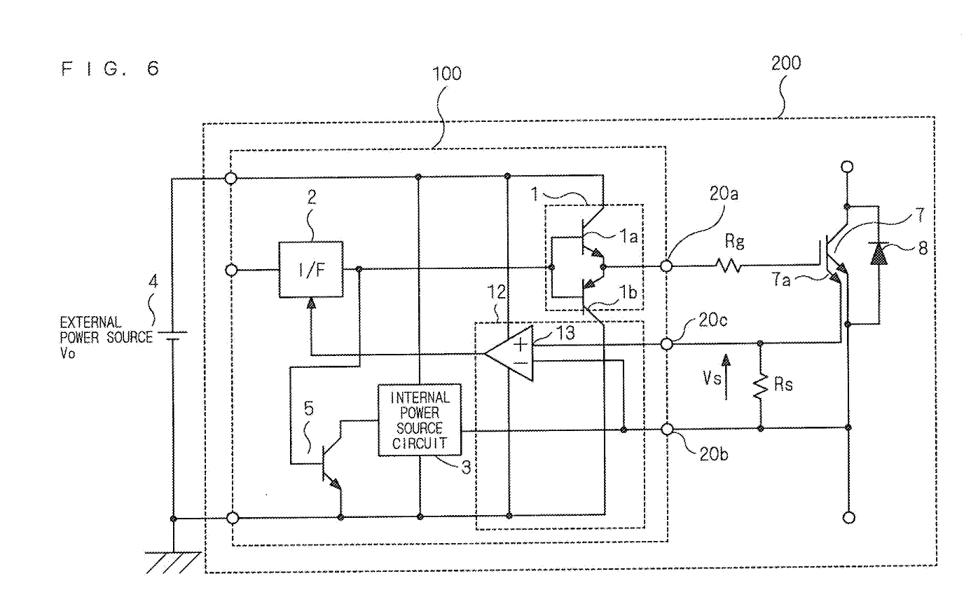

FIG. 6 is a circuit diagram of the semiconductor driving circuit 100 according to a fourth preferred embodiment of the present invention. The overcurrent detector 12 according to the fourth preferred embodiment includes a differential amplifier 13. The differential amplifier 13 has a positive phase input and a negative phase input which are connected across the sense resistor Rs, i.e. to the terminal 20e and the terminal 20b, respectively.

The differential amplifier 13 measures the sense voltage Vs to input the result to the interface (I/F) 2. When the input to the interface (I/F) 2 exceeds a predetermined value, the interface (I/F) 2 judges that the main current is excessively high to output the negative bias signal, thereby switching off the semiconductor switching element 7.

The positive phase input and the negative phase input of the differential amplifier 13 are connected across the sense resistor Rs. Thus, the overcurrent detector 12 is not influenced by variations in the voltage on the internal power source circuit 3 due to the operation of the semiconductor switching element 7. Thus, the overcurrent detector 12 is prevented from causing false detection.

In the semiconductor driving circuit 100 according to the fourth preferred embodiment, the overcurrent detector 12 is characterized by including the differential amplifier 13. Thus, when the positive phase input and the negative phase input of the differential amplifier 13 are connected across the sense resistor Rs, the overcurrent detector 12 is not influenced by variations in the voltage on the internal power source circuit 3 due to the operation of the semiconductor switching element 7. Thus, the overcurrent detector 12 is prevented from causing false detection. If the accuracy of the internal power source circuit 3 is not good, the overcurrent detector 12 is not influenced by the accuracy of the internal power source circuit 3. Thus, the detection accuracy is improved.

The preferred embodiments according to the present invention may be arbitrarily combined, modified and omitted, as appropriate, within the scope of the present invention.

While the invention has been described in detail, the foregoing description is in all aspects illustrative and not restrictive. It is understood that numerous other modifications and variations can be devised without departing from the scope of the invention.

What is claimed is:

1. A semiconductor driving circuit for driving a semiconductor switching element comprising:
an internal power source circuit for generating a second voltage from a first voltage supplied from an external power source; and
a driver for applying said first voltage or said second voltage between the gate and emitter of said semiconductor switching element in accordance with an input signal inputted from outside to switch on and off said semiconductor switching element,
said internal power source circuit being configured to operate in accordance with said input signal.

2. The semiconductor driving circuit according to claim 1, further comprising
a switching circuit switched on and off in accordance with said input signal,
wherein said internal power source circuit includes a Zener diode for generating said second voltage and connected in parallel with said switching circuit.

3. The semiconductor driving circuit according to claim 1, wherein
said semiconductor switching element includes a sense element through which current flows in any ratio to a main current of said semiconductor switching element,
said semiconductor driving circuit further comprising
an overcurrent detector for detecting a sense current flowing through said sense element, said overcurrent detector being configured to switch off said semiconductor switching element when said sense current exceeds a predetermined value.

4. The semiconductor driving circuit according to claim 2, wherein
said semiconductor switching element includes a sense element through which current flows in any ratio to a main current of said semiconductor switching element,
said semiconductor driving circuit further comprising
an overcurrent detector for detecting a sense current flowing through said sense element, said overcurrent detector being configured to switch off said semiconductor switching element when said sense element exceeds a predetermined value.

5. The semiconductor driving circuit according to claim 3, wherein
said overcurrent detector has a reference potential equal to the reference potential of said first voltage.

6. The semiconductor driving circuit according to claim 4, wherein
said overcurrent detector has a reference potential equal to the reference potential of said first voltage.

7. The semiconductor driving circuit according to claim 3, wherein
said overcurrent detector includes a differential amplifier.

8. The semiconductor driving circuit according to claim 4, wherein
said overcurrent detector includes a differential amplifier.

9. A semiconductor device comprising:
a semiconductor switching element; and
a semiconductor driving circuit for driving said semiconductor switching element,
said semiconductor driving circuit including
an internal power source circuit for generating a second voltage from a first voltage supplied from an external power source, and
a driver for applying said first voltage or said second voltage between the gate and emitter of said semiconductor switching element in accordance with an input signal inputted from outside to switch on and off said semiconductor switching element,
said internal power source circuit being configured to operate in accordance with said input signal.

10. The semiconductor device according to claim 9,
wherein said semiconductor driving circuit further includes a switching circuit switched on and off in accordance with said input signal, and
wherein said internal power source circuit includes a Zener diode for generating said second voltage and connected in parallel with said switching circuit.

11. The semiconductor device according to claim 9,
wherein said semiconductor switching element includes a sense element through which current flows in any ratio to a main current of said semiconductor switching element, and
wherein said semiconductor driving circuit further includes an overcurrent detector for detecting a sense current flowing through said sense element, said overcurrent detector being configured to switch off said semiconductor switching element when said sense current exceeds a predetermined value.

12. The semiconductor device according to claim 10,
wherein said semiconductor switching element includes a sense element through which current flows in any ratio to a main current of said semiconductor switching element, and
wherein said semiconductor driving circuit further includes an overcurrent detector for detecting a sense current flowing through said sense element, said overcurrent detector being configured to switch off said semiconductor switching element when said sense current exceeds a predetermined value.

13. The semiconductor device according to claim 11, wherein
said overcurrent detector has a reference potential equal to the reference potential of said first voltage.

14. The semiconductor device according to claim 11, wherein
said overcurrent detector includes a differential amplifier.

15. The semiconductor device according to claim 9, wherein
said semiconductor switching element contains SiC.

16. The semiconductor device according to claim 10, wherein
said semiconductor switching element contains SiC.

17. The semiconductor device according to claim 11, wherein
said semiconductor switching element contains SiC.

18. The semiconductor device according to claim 9, wherein
said semiconductor switching element contains GaN.

19. The semiconductor device according to claim 10, wherein
said semiconductor switching element contains GaN.

20. The semiconductor device according to claim 11, wherein
said semiconductor switching element contains GaN.
